(19) United States
(12) Patent Application Publication
(10) Pub. No.: US 2012/0235252 A1
(43) Pub. Date: Sep. 20, 2012

(54) MANUFACTURING METHOD FOR AN ENCAPSULATED MICROMECHANICAL COMPONENT, CORRESPONDING MICROMECHANICAL COMPONENT, AND ENCAPSULATION FOR A MICROMECHANICAL COMPONENT

(76) Inventor: Stefan Pinter, Reutlingen (DE)

(21) Appl. No.: 13/393,412

(22) PCT Filed: Aug. 2, 2010
(86) PCT No.: PCT/EP2010/061185

§ 371 Date: May 16, 2012

(30) Foreign Application Priority Data
Sep. 3, 2009 (DE) 10 2009 029 184.9

(51) Int. Cl. H01L 29/84; H01L 23/28; H01L 21/02

(52) U.S. Cl. 257/415; 438/51; 257/787; 257/E23.116; 257/E29.324; 257/E21.002

(57) ABSTRACT

A manufacturing method for an encapsulated micromechanical component has the following steps: creating an intermediate substrate having a plurality of perforations; laminating an encapsulation substrate onto a front side of the intermediate substrate, which closes the perforations on the front side; laminating an MEMS functional wafer onto a rear side of the intermediate substrate; the MEMS functional wafer being aligned with the intermediate substrate in such a way that the perforations form cavities over the corresponding functional areas of the MEMS functional wafer.

### BACKGROUND OF THE INVENTION

1. Field of the Invention

The present invention relates to a manufacturing method for an encapsulated micromechanical component, a corresponding micromechanical component, and an encapsulation for a micromechanical component.

2. Description of Related Art

Although it is applicable to any desired micromechanical components, the present invention and the background on which it is based will be explained with respect to micromechanical components in silicon technology.

MEMS components (MEMS=micro-electromechanical systems) must be protected from harmful external environmental influences, such as moisture, aggressive media, etc. Protection from mechanical contact/destruction and to allow the isolation from a wafer composite into chips by sawing is also necessary.

In the past few years, the encapsulation of MEMS components using a capping wafer made of silicon, glass, or a composite of both, which has cavities and through-holes, has established itself in wafer composites. For this purpose, a capping wafer is aligned with the wafer having the MEMS structures and joined thereto. The joining may be performed via anodic bonding (connection free of joint compound between glass and silicon), via eutectic joining layers, and via glass solders or adhesives. The MEMS components are located under cavities of the capping wafer. Electrical bond pads for electrically connecting the component to thin wires are accessible via through-holes in the capping wafer.

For optical MEMS (MOEMS), such as for micro-mirrors, the above-described protection, the through-holes for the electrical connections, and also an optical window over each cavity having high quality and optionally also having specific optical coatings are necessary.

Previous applications, e.g., micromechanical sensors for measuring acceleration, yaw rate, and pressure, place high demands on the hermetic seal of the encapsulation. For this reason, predominantly costly hermetic encapsulation methods using glass and/or silicon wafers have established themselves over anodic bonding, glass solder bonding, or eutectic bonding.

For more recent applications, which require protection from mechanical contact/destruction and to allow the isolation by sawing, but do not place very high demands on the hermetic seal of the encapsulation, other, more cost-effective materials have been developed for the protective encapsulation or other joining methods.

In more recent years, a novel encapsulation method, thin-film encapsulation, has been developed in particular, which dispenses with a capping wafer and instead forms a hollow space or a cavern as the encapsulation layer between the micromechanical structures to be exposed and a silicon layer generated using a typical deposition process.

A method for manufacturing a micromechanical component having an encapsulation layer is known from published German patent application document DE 10 2006 049 259 A1, an encapsulation layer being deposited on a filling layer and micropores being subsequently produced in the encapsulation layer. The filling layer is subsequently removed by gas phase etching using ClF₃ guided thereto through the micropores, the selectivity of the etching mixture and the composition of the filling layer being set in such a way that the selectivity in relation to the encapsulation layer is sufficiently large so that it is not attacked. After removing the filling layer, the micropores are sealed by depositing a closure layer.

Published German patent application document DE 10 2007 022 509 A1 discloses a manufacturing method for a micromechanical component using thin-film encapsulation, a gas being enclosed in the cavern which has a non-atmospheric composition because of the decomposition of a polymer.

### BRIEF SUMMARY OF THE INVENTION

The manufacturing method according to the present invention for an encapsulated micromechanical component is distinguished by low manufacturing costs. Optical windows or also electrical through-contacts and printed conductors are integratable into the encapsulation substrate.

The core of the present invention is that perforations are provided by stamping, for example, in an intermediate substrate, such as a plastic film and two optional adhesive layers, at the locations of the later cavities. The intermediate substrate is then laminated onto an unstamped encapsulation substrate, e.g., an additional plastic film.

The material of both substrates, i.e., encapsulation substrate and intermediate substrate, may subsequently be stamped out in the composite at the locations of the possibly desired through-holes. The product is a resulting laminate having cavities and through-holes. The resulting laminate is finally laminated onto the MEMS functional wafer.

For example, biaxially oriented polyester films (boPET), such as Mylar®, Melinex®, or Teonex®, having high thermostability even at elevated temperatures, are suitable as the plastic films for the laminate or the encapsulation substrate and intermediate substrate. To reduce the permeation rate for moisture and gases to the desired extent, metallic layers may be provided on or in the laminate. They are available in opaque embodiments and transparent embodiments in thicknesses of approximately 50 μm to 1400 μm.

Adhesive layers or protective films may also be applied on one or both sides in the intermediate substrate or encapsulation substrate. The cavities may also be readily embossed in these adhesive layers or protective films in the intermediate substrate. No additional process for the application of joining layers is required due to the adhesive layers which are already applied to the appropriate films. Easier handling is possible if additional protective films are provided.

Since layers of this type are used in electronics for flexible printed boards, they are also available in a solderable embodiment having various coatings (lacquers, inks, photosensitive emulsions, or also having copper layers for electrical printed conductors and through-contacts). The substrate film material is not restricted to the above-mentioned materials. Of course, other materials, which are suitable for printed boards, for example, may also be used.

In addition to the above-mentioned advantages, the present invention offers the advantage that the encapsulation substrate or the intermediate substrate having very small thicknesses is implementable. Simple, rapid, and cost-effective sawing or another type of isolation is also possible.

A laminate of the plastic films in combination with silicon or glass or other wafer materials is also readily possible.

### BRIEF DESCRIPTION OF THE DRAWINGS

FIGS. 1a-h show schematic cross-sectional views to explain a manufacturing method for an encapsulated micromechanical component according to a first specific embodiment of the present invention.

FIGS. 2a-e show schematic cross-sectional views to explain a manufacturing method for an encapsulated micromechanical component according to a second specific embodiment of the present invention.

### DETAILED DESCRIPTION OF THE INVENTION

The same reference numerals identify identical or functionally identical elements in the figures.

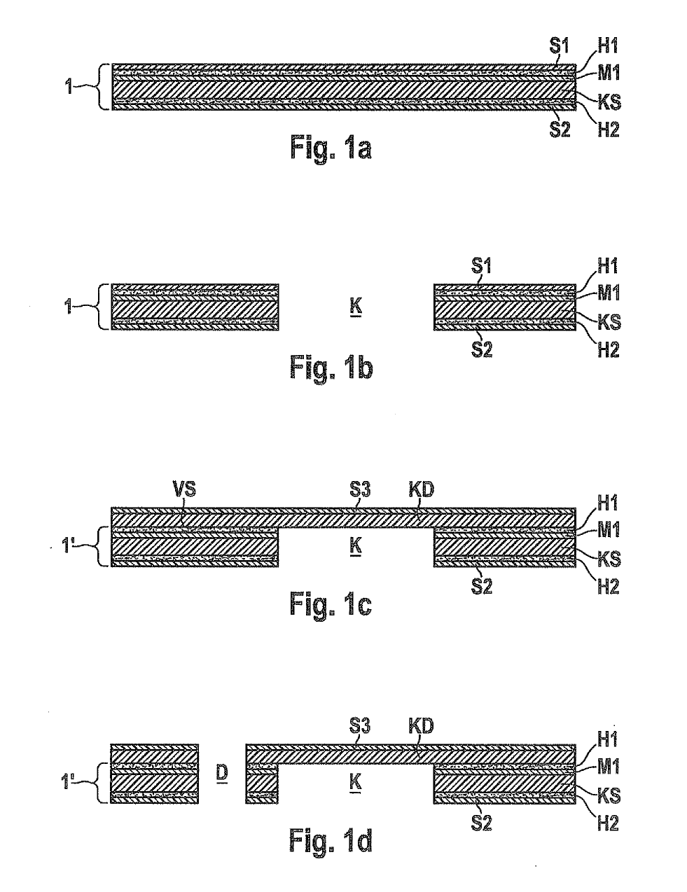

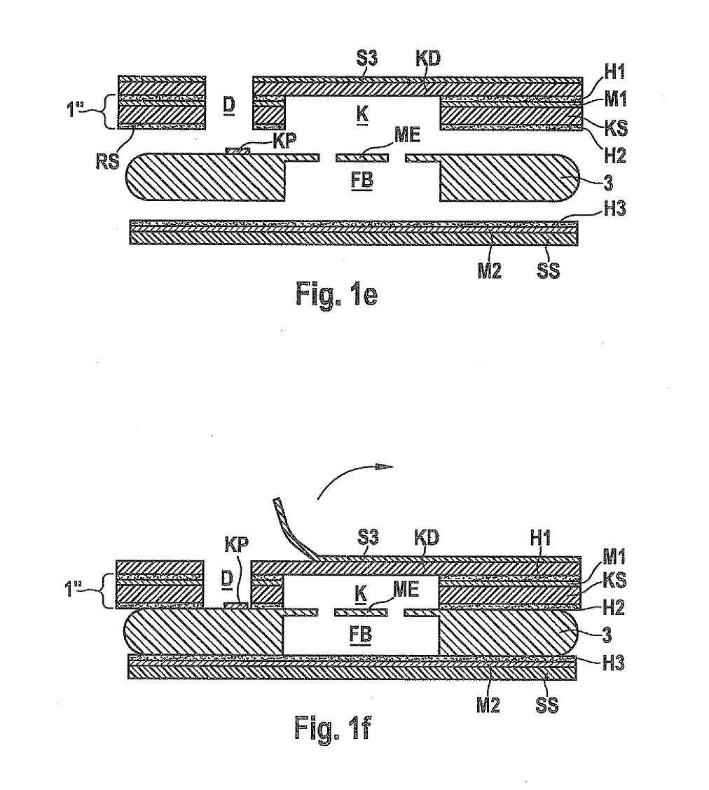

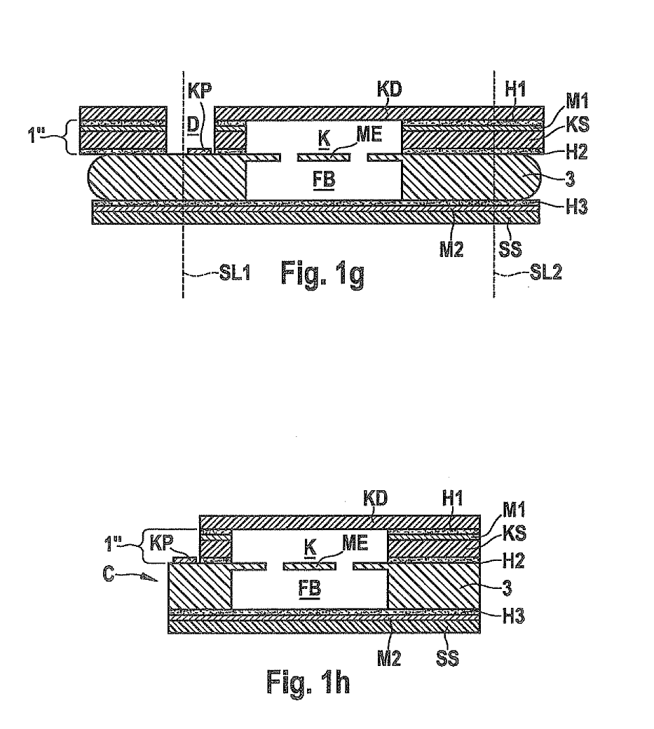

FIGS. 1a-h show schematic cross-sectional views to explain a manufacturing method for an encapsulated micromechanical component according to a first specific embodiment of the present invention.

In FIG. 1a, reference numeral 1 identifies an intermediate substrate, which has the following components: a plastic film KS made of Mylar®, Melinex®, or Teonex®, for example, a metal layer M1, which is sputtered thereon, made of aluminum, a first adhesive layer H1, which is provided on metal layer M1, made of a plastic adhesive, a second adhesive layer H2, which is provided below plastic film KS, made of a plastic adhesive, a first protective film S1 on first adhesive layer H1, and a second protective film S2 on second adhesive layer H2. The core component of intermediate substrate 1 is plastic film KS, the remaining layers being optional.

As shown in FIG. 1b, a micro-stamping step is then performed to generate perforations K where cavities of the micromechanical component to be encapsulated will later be located.

Furthermore, with reference to FIG. 1c, frontal protective film S1 of intermediate substrate 1 is removed and, on this side, an encapsulation substrate KD made of an additional plastic film made of Mylar®, Melinex®, or Teonex®, or a wafer material, for example, is laminated onto exposed frontal first adhesive layer H1. Encapsulation substrate KD optionally also carries a protective film on the top side, which is identified by reference numeral S3. Through this lamination, encapsulation substrate KD closes perforations K on front side VS of intermediate substrate 1′, which has been freed of first protective film S1.

As shown in FIG. 1d, through openings D are subsequently provided in intermediate substrate 1′ and laminated-on encapsulation substrate KD having protective film S3, which are laterally offset in relation to perforations K. These through-holes D are later to make contact areas KP of MEMS functional wafer 3 accessible (compare FIG. 1e).

As shown in FIG. 1e, in a following step, the laminate, which is made up of intermediate substrate 1″, which has been freed of second protective film S2, and of encapsulation substrate KD, is aligned in relation to MEMS functional wafer 3, which is to be encapsulated, having a plurality of components, in such a way that perforations K (only one of which is shown in FIG. 1) each form cavities over corresponding functional areas FB of MEMS functional wafer 3. Through-holes D (only one of which is shown in FIG. 1) are also aligned in such a way that they are situated over corresponding contact areas KP of MEMS functional wafer 3.

In addition, in the present exemplary embodiment a base substrate SS made of glass, which is optionally coated using a metal layer M2 made of aluminum and an adhesive layer H3, which is located above it, made of plastic adhesive, is aligned with the rear side of the MEMS functional wafer in order to close from there hollowed-out functional areas FB, each of which has a diaphragm area ME. Functional areas FB of this type may have structures of a micro-mirror, for example.

After completed alignment according to FIG. 1e, as shown in FIG. 1f, base substrate SS, MEMS function layer 3, and intermediate substrate 1″, which is bonded to encapsulation substrate KD, are joined under pressure and optionally at elevated temperature to form the composite shown in FIG. 1f. Subsequently thereto, protective film S3 is removed from the top side of encapsulation substrate KD by being pulled off.

Furthermore, with reference to FIG. 1g, the components are isolated by sawing, schematic saw lines SL1, SL2 being indicated in FIG. 1g.

After the sawing, encapsulated chip C shown in FIG. 1h is obtained, which is a micro-mirror chip in the present example.

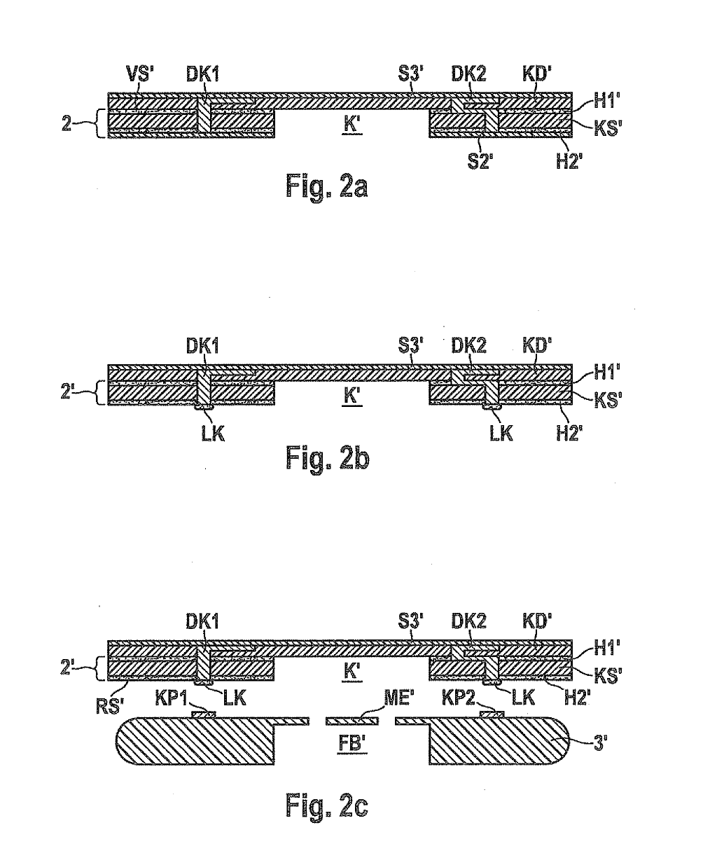

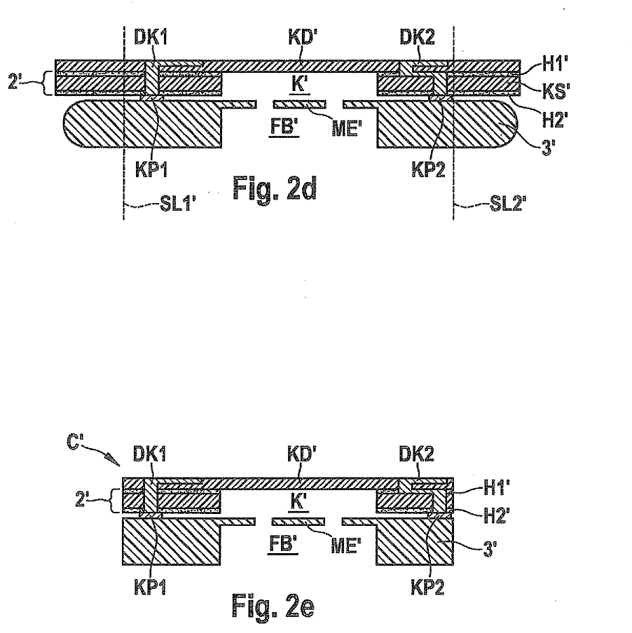

FIGS. 2a-e show schematic cross-sectional views to explain a manufacturing method for an encapsulated micromechanical component according to a second specific embodiment of the present invention.

The process state of the second exemplary embodiment shown in FIG. 2a corresponds to the process state of the first exemplary embodiment shown in FIG. 1c.

In contrast to the first exemplary embodiment, intermediate substrate 2 of the second exemplary embodiment does not have a metal layer on its front side VS′, but rather adhesive layer H1′ is applied to plastic film KS′. A rear adhesive layer H2′ having protective film S2′ located above it is also applied to plastic film KS′. Encapsulation substrate KD′, which is laminated onto intermediate substrate 2, carries a frontal protective film S3′.

Furthermore, the second specific embodiment differs from the first specific embodiment in that no through-holes D are provided, but rather a rewiring device DK1, DK2, which extends from the rear side of adhesive layer HS′ up to the front side of encapsulation substrate KD′, is provided in intermediate substrate 2 and in encapsulation substrate KD′.

After rear protective film S2′ is pulled off, as shown in FIG. 2b, conductive adhesive LK is applied to the exposed areas of through-contacts DK1, DK2 on the rear side of the laminate made of intermediate substrate 2′ and encapsulation substrate KD′. This may be performed by screen printing, for example.

The alignment of the laminate made of intermediate substrate 2′, which has been freed from protective film S2′, having laminated-on encapsulation substrate KD′ with MEMS functional wafer 3′, which has a functional area FB′ having a diaphragm area ME′, is shown in FIG. 2c. In this specific embodiment, in addition to functional area FB′, contact areas KP1 and KP2 are provided on the top side of MEMS functional wafer 3′.

The placing is performed similarly to the above first exemplary embodiment in such a way that perforations K′ each form cavities over corresponding functional areas FB′ having diaphragm areas ME′ of MEMS functional wafer 3′, and that rewiring devices DK1, DK2 are situated over corresponding contact areas KP1, KP2 of MEMS functional wafer 3′.

After completed alignment, the lamination is performed under pressure and optionally under elevated temperature, which results in the process state according to FIG. 1d.

A rear encapsulation by a base substrate is not provided in this exemplary embodiment, but is optionally also possible.

In accordance with FIG. 1g, saw lines SL1′ and SL2′ are provided in FIG. 2d, along which the wafer is sawn into individual chips C′ for isolation, as shown in FIG. 2e.

Although the present invention was described above on the basis of preferred exemplary embodiments, it is not restricted thereto, but rather is modifiable in manifold ways.

The materials, in particular, are only mentioned as examples and are replaceable by other materials which have the required mechanical and/or optical properties.

Although the metal layer on the intermediate substrate was a sputtered aluminum layer in the above-described first exemplary embodiment, other coatings, which are optically effective, for example, may also be provided, such as a filter coating, an antireflection coating, a polarization coating, etc.

Although in the above-described specific embodiments plastic films, such as Mylar®, Melinex®, or Teonex®, were mentioned as examples for the intermediate substrate and the encapsulation substrate, and glass was mentioned for the base substrate, other materials may also be used for these substrates.

Substrates KS, KD, or SS may in principle also be made of metal films, glass, silicon, or another suitable plastic.

1-15. (canceled)

16. A method for manufacturing a micromechanical component, comprising:
providing an intermediate substrate having a plurality of perforations;
laminating an encapsulation substrate onto a front side of the intermediate substrate to close the perforations on the front side; and
laminating an MEMS functional wafer onto a rear side of the intermediate substrate;
wherein the MEMS functional wafer is aligned with the intermediate substrate in such a way that the perforations form cavities over corresponding functional areas of the MEMS functional wafer.

17. The method as recited in claim 16, wherein at least one of the intermediate substrate and the encapsulation substrate has a plastic film.

18. The method as recited in claim 16, wherein a front adhesive layer and a rear adhesive layer are applied on the intermediate substrate.

19. The method as recited in claim 16, wherein the intermediate substrate has a metal layer on the front side.

20. The method as recited in claim 16, wherein the intermediate substrate has a front protective film and a rear protective film, and wherein the front and rear protective films are removed after the formation of the perforations for the lamination of the encapsulation substrate and the MEMS functional wafer.

21. The method as recited in claim 16, wherein, after the lamination of the encapsulation substrate and before the lamination of the MEMS functional wafer, through-holes extending through the intermediate substrate and the laminated-on encapsulation substrate are formed laterally offset to the perforations, and wherein the MEMS functional wafer is aligned with the intermediate substrate during the lamination of the MEMS functional wafer in such a way that the through-holes are situated over corresponding contact areas of the MEMS functional wafer.

22. The method as recited in claim 16, wherein a rewiring device is provided in the intermediate substrate and in the encapsulation substrate, and wherein the MEMS functional wafer is aligned with the intermediate substrate during the lamination of the MEMS functional wafer in such a way that the rewiring device is situated over corresponding contact areas of the MEMS functional wafer.

23. The method as recited in claim 22, wherein a conductive adhesive is provided between the rewiring device and the corresponding contact areas of the MEMS functional wafer before the lamination of the MEMS functional wafer.

24. The method as recited in claim 21, wherein a top protective film is provided on the encapsulation substrate, and wherein the top protective film is removed after the lamination of the MEMS functional wafer.

25. The method as recited in claim 21, wherein a base substrate is laminated onto the side of the MEMS functional wafer which is opposite to the encapsulation substrate.

26. The method as recited in claim 21, wherein the functional areas of the MEMS functional wafer each have a diaphragm area.

27. A micromechanical component, comprising:
an intermediate substrate having a plurality of perforations;
an encapsulation substrate laminated onto a front side of the intermediate substrate and closing the perforations on the front side of the intermediate substrate; and
an MEMS functional wafer laminated onto a rear side of the intermediate substrate, wherein the MEMS functional wafer is aligned with the intermediate substrate in such a way that the perforations form cavities over corresponding functional areas of the MEMS functional wafer.

28. The micromechanical component as recited in claim 27, through-holes extending through the intermediate substrate and the laminated-on encapsulation substrate are provided, and wherein the MEMS functional wafer is aligned with the intermediate substrate in such a way that the through-holes are situated over corresponding contact areas of the MEMS functional wafer.

29. The micromechanical component as recited in claim 27, wherein a rewiring device is provided in the intermediate substrate and in the encapsulation substrate, and wherein the MEMS functional wafer is aligned with the intermediate substrate in such a way that the rewiring device is situated over corresponding contact areas of the MEMS functional wafer.

30. An encapsulation for a micromechanical component, comprising:
an intermediate substrate having a plurality of perforations; and
an encapsulation substrate laminated onto a front side of the intermediate substrate and closing the perforations on the front side of the intermediate substrate.
